(19) United States
(12) Patent Application Publication
(10) Pub. No.: US 2023/0213569 A1
(43) Pub. Date: Jul. 6, 2023

(54) SYSTEMS AND METHODS FOR ESTIMATING POWER LOSS USING POINT-TO-POINT DIFFERENTIAL LOAD CALCULATIONS

(71) Applicants: Duke Energy Corporation, Charlotte, NC (US); A-PLUS Community Solutions, Inc., Roswell, GA (US)

(72) Inventors: Ron K. Wages, Waxhaw, NC (US); Larry J. Morrow, Nashville, GA (US)

(21) Appl. No.: 18/057,450

(22) Filed: Nov. 21, 2022

Related U.S. Application Data
(60) Provisional application No. 63/266,303, filed on Dec. 31, 2021.

(51) Int. Cl. G01R 31/08; G06Q 50/06

(52) U.S. Cl. CPC G01R 31/085; G06Q 50/06

(57) ABSTRACT

Systems, apparatuses, methods, and computer program products are disclosed for predicting causes of changes in power loss along electric line segments. An example method includes receiving, by a control system, telemetry data from a set of devices in an electrical grid and storing, by the control system, the telemetry data in a memory. The example method further includes calculating, by the control system and using the telemetry data, a change in impedance in an electric line segment between two devices from the set of devices and determining, by the control system, a cause of the change in the impedance in the electric line segment between the two devices. Corresponding apparatuses and computer program products are also disclosed.

### CROSS REFERENCE TO RELATED APPLICATIONS

The present application claims the benefit of U.S. Provisional Application No. 63/266,303, filed Dec. 31, 2021, which is hereby incorporated by reference in its entirety.

### TECHNOLOGICAL FIELD

The present disclosure relates in general to the field of electrical power distribution, and more specifically, to systems for using telemetry data received from active devices in an electric grid to measure and predict power loss from physical and environmental changes affecting electric lines.

### BACKGROUND

Modern power distribution grids include many generation and transmission resources used to provide power to different types of user loads. Generation and transmission resources may include generators, transmission lines, substations, transformers, etc.

FIG. 1 is a simplified block diagram illustrating an example electrical power distribution environment 100. Referring to FIG. 1, electric power may be generated at a power generation facility 110 for distribution to users 140A-140N that consume the generated electric power. Examples of power generation facilities 110 include facilities which generate electricity from fossil fuels (e.g., coal, petroleum, and/or natural gas), solar energy, geothermal energy, nuclear energy, potential energy (e.g., with a hydroelectric facility), wind energy, and/or chemical energy.

Once generated at the power generation facility 110, the electricity may be delivered to the users 140A-140N via a power distribution grid. The power grid may include, for example, power transmission lines 115 between the power generation facility 110 and one or more substations 120. The electricity may be further transmitted from a given substation 120 to one or more of users 140A-140N over electrical distribution circuits 130, also known as feeders. For example, the electrical distribution circuit 130 may provide electricity to any one of users 140A-140N via a connection between the electrical distribution circuit 130 and the location (e.g., house or building) of the user, such as, for example, at a power meter. The electrical distribution circuits 130 may include, for example, both overhead and underground power lines. Electrical distribution circuits 130 may include additional segmentation. For example, an electrical distribution circuit 130 may include one or more protective devices 135. Protective devices 135 may include, for example, switches, circuit breakers, and/or reclosers.

Given the scale of the power distribution grid, vegetation management is one of the largest operation and maintenance (O&M) expenses that utilities must bear. Historically, vegetation issues have been identified in an ad hoc fashion, with electric utility operators relying on calls from customers to indicate a loss of power or other trouble faults that may be caused by environmental factors. Trouble faults causing issues include, but are not limited to, line stretches, environmental changes, atmospheric changes, and line breaks. However, customers generally do not call unless they have lost power, so traditional techniques for vegetation management are often reactive, and generally do not enable preventative maintenance. Accordingly, a need exists for new tools and techniques for identifying and classifying power loss based on physical and environmental changes to electric lines.

### BRIEF SUMMARY

As described herein, example embodiments utilize a fiber optic network connecting various active devices in the electric grid to enable the capture of impedance, voltage, and current at various points along line segments in the electric grid. Leveraging the data gathered from the various active devices in the electric grid, example embodiments produce evolving estimates of power loss for the various line segments in the electric grid. From this estimated power loss information, a control system can systematically identify the extent of vegetation and other environmental causes of power loss, and in turn may optimize efficiency of the utility's operations and maintenance program spend by prioritizing the resolution of the various environmental issues.

To this end, systems, apparatuses, methods, and computer program products are disclosed herein for estimating power loss based on physical and environmental changes affecting electric lines and predicting the causes of changes in power loss along electric line segments over time. An example method includes receiving, by a control system, telemetry data from a set of devices in an electrical grid and storing, by the control system, the telemetry data in a memory. The example method further includes calculating, by the control system and using the telemetry data, a change in impedance in an electric line segment between two devices from the set of devices, and determining, by the control system, a cause of the change in the impedance in the electric line segment between the two devices.

In one example embodiment, an apparatus is provided for estimating power loss based on physical and environmental changes affecting electric lines and predicting the causes of changes in power loss along electric line segments over time. The example apparatus includes a processor and a memory storing software instructions that, when executed by the processor, cause the apparatus to receive telemetry data from a set of devices in an electrical grid and store the telemetry data in a memory. The processor and the memory storing software instructions, when executed by the processor, further cause the apparatus to calculate, using the telemetry data, a change in impedance in an electric line segment between two devices from the set of devices, and determine a cause of the change in the impedance in the electric line segment between the two devices.

In one example embodiment, a computer program product is provided for estimating power loss based on physical and environmental changes affecting electric lines and predicting the causes of changes in power loss along electric line segments over time. The computer program product includes at least one non-transitory computer-readable storage medium storing software instructions that, when executed by an apparatus, cause the apparatus to receive telemetry data from a set of devices in an electrical grid and store the telemetry data in a memory. The at least one non-transitory computer-readable storage medium storing software instructions, when executed by the apparatus, further cause the apparatus to calculate, using the telemetry data, a change in impedance in an electric line segment between two devices from the set of devices, and determine a cause of the change in the impedance in the electric line segment between the two devices.

The foregoing brief summary is provided merely for purposes of summarizing some example embodiments described herein. Because the above-described embodiments are merely examples, they should not be construed to narrow the scope of this disclosure in any way. It will be appreciated that the scope of the present disclosure encompasses many potential embodiments in addition to those summarized above, some of which will be described in further detail below.

### BRIEF DESCRIPTION OF THE FIGURES

Having described certain example embodiments in general terms above, reference will now be made to the accompanying drawings, which are not necessarily drawn to scale. Some embodiments may include fewer or more components than those shown in the figures.

FIG. 1 illustrates a simplified block diagram illustrating an example electrical power distribution environment.

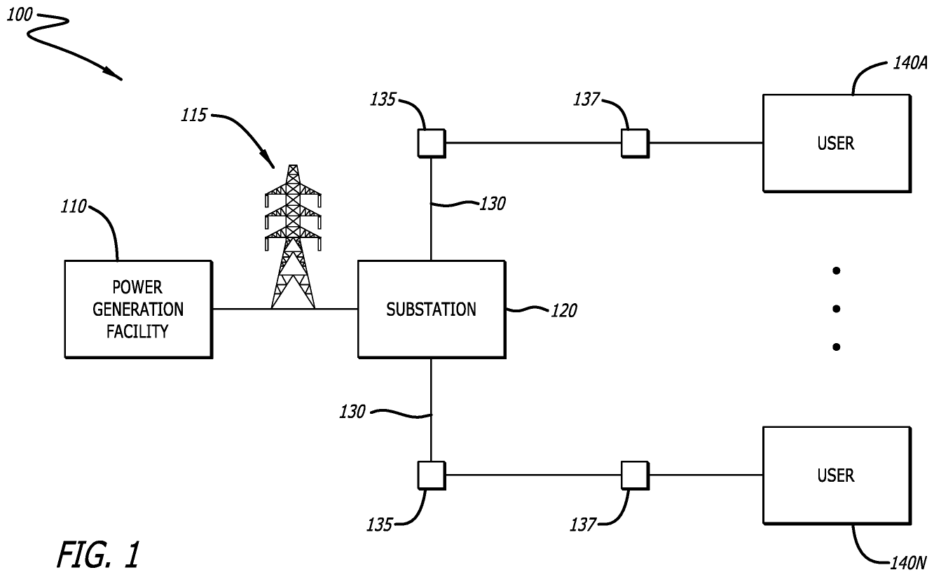

FIG. 2A illustrates a simplified block diagram of an example electrical power distribution environment and corresponding fiber optic network, in accordance with some example embodiments described herein.

FIG. 2B illustrates vegetation that may be affecting the delta impedance in electric line segments between various customer premises, in accordance with some example embodiments described herein.

FIG. 2C illustrates a diagram of a customer premise along with corresponding devices near the customer premise, in accordance with some example embodiments described herein.

FIG. 3 illustrates a schematic block diagram of example circuitry embodying a device that may perform various operations in accordance with example embodiments described herein.

FIG. 4 illustrates an example flowchart for predicting causes of changes in power loss along electric line segments, in accordance with some example embodiments described herein.

FIG. 5 illustrates an example graph showing delta impedance between two premises at a first time, in accordance with some example embodiments described herein.

FIG. 6 illustrates an example graph showing delta impedance between two premises at a second time, in accordance with some example embodiments described herein.

FIG. 7 illustrates an example flowchart for a machine learning model training routine, in accordance with some example embodiments described herein.

### DETAILED DESCRIPTION

Some example embodiments will now be described more fully hereinafter with reference to the accompanying figures, in which some, but not necessarily all, embodiments are shown. Because inventions described herein may be embodied in many different forms, the invention should not be limited solely to the embodiments set forth herein; rather, these embodiments are provided so that this disclosure will satisfy applicable legal requirements.

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly describe herein are also contemplated as may be set forth in some of the appended claims. Although specific terms are employed herein, they are used in a generic and descriptive sense only and not for purposes of limitation.

The terms “data,” “content,” “information,” “electronic information,” “signal,” “command,” and similar terms may be used interchangeably to refer to data capable of being transmitted, received, and/or stored in accordance with embodiments of the present invention. Thus, use of any such terms should not be taken to limit the spirit or scope of embodiments of the present invention. Further, where a first computing device is described herein to receive data from a second computing device, it will be appreciated that the data may be received directly from the second computing device or may be received indirectly via one or more intermediary computing devices, such as, for example, one or more servers, relays, routers, network access points, base stations, hosts, and/or the like, sometimes referred to herein as a “network.” Similarly, where a first computing device is described herein as sending data to a second computing device, it will be appreciated that the data may be sent directly to the second computing device or may be sent indirectly via one or more intermediary computing devices, such as, for example, one or more servers, remote servers, cloud-based servers (e.g., cloud utilities), relays, routers, network access points, base stations, hosts, and/or the like.

The terms “comprising” means including but not limited to, and should be interpreted in the manner it is typically used in the patent context. Use of broader terms such as comprises, includes, and having should be understood to provide support for narrower terms such as consisting of, consisting essentially of, and comprised substantially of.

The terms “in one embodiment,” “according to one embodiment,” “in some embodiments,” and the like generally may refer to the fact that the particular feature, structure, or characteristic following the phrase may be included in at least one embodiment of the present invention. Thus, the particular feature, structure, or characteristic may be included in more than one embodiment of the present invention such that these phrases do not necessarily refer to the same embodiment.

The term “example” is used herein to mean “serving as an example, instance, or illustration.” Any implementation described herein as “example” is not necessarily to be construed as preferred or advantageous over other implementations.

The terms “computer-readable medium” and “memory” refer to non-transitory storage hardware, non-transitory storage device or non-transitory computer system memory that may store computer-executable instructions or software programs that may be accessed by a controller, a microcontroller, a computational system or a module of a computational system. A non-transitory computer-readable medium may be accessed by a computational system or a module of a computational system to retrieve and/or execute the computer-executable instructions or software programs stored on the medium. Exemplary non-transitory computer-readable media may include, but are not limited to, one or more types of hardware memory, non-transitory tangible media (for example, one or more magnetic storage disks, one or more optical disks, one or more USB flash drives), computer system memory or random access memory (such as, DRAM, SRAM, EDO RAM), and the like.

The term “computing device” may refer to any computer embodied in hardware, software, firmware, and/or any combination thereof. Non-limiting examples of computing devices include a personal computer, a server, a laptop, a mobile device, a smartphone, a fixed terminal, a personal digital assistant (“PDA”), a kiosk, a custom-hardware device, a wearable device, a smart home device, an Internet-of-Things (“IoT”) enabled device, and a network-linked computing device.

The term “control system” is used herein to refer to any one or all of programmable logic controllers (PLCs), programmable automation controllers (PACs), industrial computers, desktop computers, personal data assistants (PDAs), laptop computers, tablet computers, smart books, palm-top computers, personal computers, smartphones, server devices, and similar electronic devices equipped with at least a processor and any other physical components necessary to perform the various operations described herein.

The term “fiber optic network” is used herein to refer to a communication network which includes one or more optical fiber cables, which may be used facilitate the transfer of a signal (e.g., telemetry data) between respective terminals (e.g., a starting node or optical line terminal (OLT) and a terminating node or optical network terminal (ONT)). At least a portion of each optical fiber cable may further be disposed within a cable jacket, which may serve to protect the optical fiber cable from environmental conditions and ensure long-term durability. Additionally, the cable jacket may minimize attenuation of carried signals due to microbleeding. In some embodiments, the fiber optic network is a passive optical network (PON). A PON may use one or more fiber optic splitters to divide individual optical fiber cables among two or more ONTs, thus reducing the number of fiber optic cables needed for connectivity and the number of active devices requiring electrical power. A PON may utilize wavelength-division multiplexing (e.g., coarse wavelength division multiplexing (CWDM or dense wavelength division multiplexing (DWDM)) to permit bidirectional communications and/or a multiplication of capacity of the fiber optic network. In some embodiments, downstream signals provided by an ONT are received by all ONTs. In some embodiments, these downstream signals are encrypted using any suitable technique to prevent eavesdropping. In some embodiments, the fiber optic terminals may correspond to terminals at a central office (CO) or head end (HE) facility and customer premise equipment (CPE) at a corresponding customer location, residential government, or commercial location.

The term “telemetry data” is used here to refer to data collected by various devices within the power distribution environment and transmitted via the fiber optic network. For example, the telemetry data may be collected by smart meters at a customer premises, transformers, down-line reclosers, and distributed power generation facilities, and/or the like. Telemetry data may be transmitted via the fiber optic network in sub-millisecond intervals. In some embodiments, the telemetry data may be encrypted using an encryption key. The encryption key may be a symmetric encryption key which is shared between two or more active devices or other devices within the fiber optic network. The encryption key may correspond to a symmetric key algorithm, such as advanced encryption standard (AES), Blowfish, data encryption standard (DES), and/or the like.

### Overview

As noted previously, vegetation issues affect a power distribution grid have historically been identified in an ad hoc fashion, and traditional techniques for vegetation management are often reactive, and generally do not enable effective scheduling and performance of maintenance. Accordingly, a need exists for new tools and techniques for identifying and classifying power loss based on physical and environmental changes to electric lines.

To address this need, example embodiments described herein rely upon an enhanced electrical power distribution environment leveraging the use of a corresponding fiber optic network that permits near-real-time exchange of information between various active devices in the environment. Through the fiber optic network, a control system can capture of impedance, voltage, and current at various points along line segments in the electric grid, and may systematically identify the extent of vegetation and other environmental causes of power loss, and in turn may optimize efficiency of the utility's operations and maintenance spending by prioritizing the resolution of the various environmental issues.

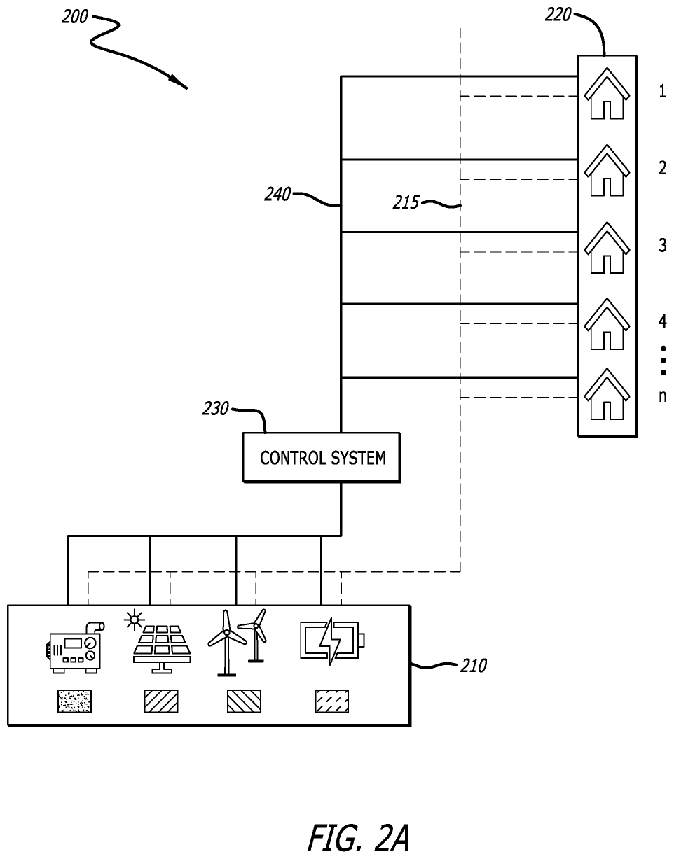

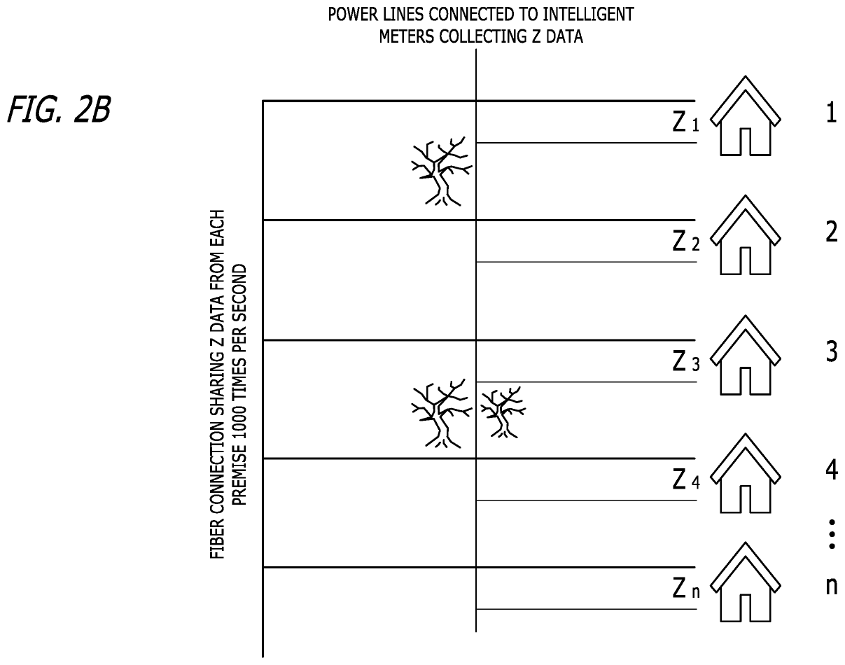

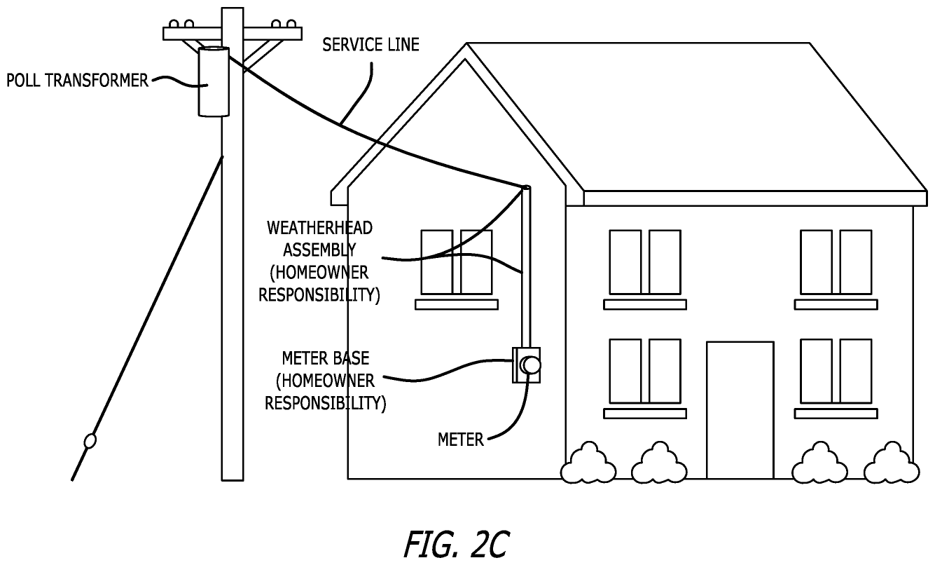

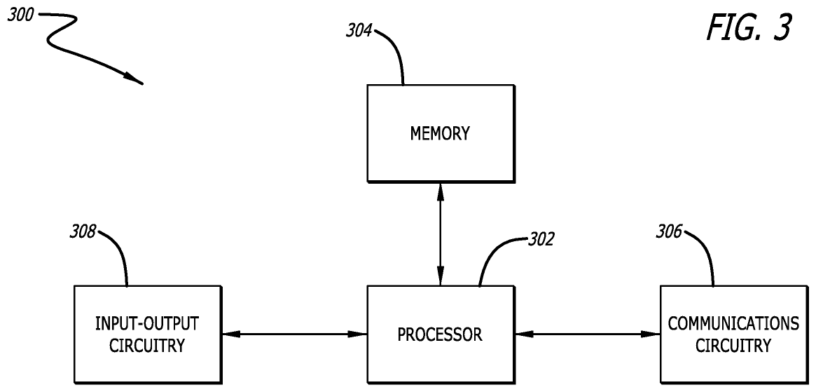

FIG. 2A illustrates a simplified block diagram of an example electrical power distribution environment 200 enhanced by a corresponding fiber optic network, in accordance with some example embodiments described herein. FIG. 2A illustrates a series of power generating facilities 210 (which may comprise facilities that generate electricity from fossil fuels, solar energy, geothermal energy, nuclear energy, potential energy (e.g., with a hydroelectric facility), wind energy, and/or chemical energy.) that may be provide power to a series of users 220 via a distribution network 215. While power generation facilitates 110 are traditionally located in fixed locations within an environment remote from heavily populated areas and connected to the rest of the environment via transmission lines, many renewable power generation facilitates (e.g., wind, solar, fuel-based generators, and battery enclaves) may be distributed throughout the environment. In addition, however, FIG. 2A illustrates a control system 230 that may exchange information with the power generating facilities 210 and the users 220 via a fiber optic network 240. Various components of the control system 230 are described in greater detail below in connection with FIG. 3. The fiber optic network 240 may connect to just the endpoints in the electrical power distribution environment 200 or may connect to all entities (including transformers, switches, circuit breakers, reclosers, etc.) in the electrical power distribution environment 200.

Optical fiber cables within the fiber optic network 240 may be used facilitate the transfer of a signal (e.g., telemetry data) between respective terminals (e.g., between OLT and ONTs). At least a portion of each optical fiber cable may further be disposed within a cable jacket, which may serve to protect the optical fiber cable from environmental conditions and ensure long-term durability. Additionally, the cable jacket may minimize attenuation of carried signals due to microbleeding. Connection of the fiber optic network to the various entities in the electrical power distribution environment 200 enables near-real-time communication between any two entities in the environment with any other entity.

The fiber optic network 240 may comprise a PON to reduce the number of fiber optic strands needed for connectivity and the number of active devices requiring electrical power, and may utilize wavelength-division multiplexing (e.g., CWDM or DWDM) to permit bidirectional communications and/or a multiplication of capacity of the fiber optic network. A PON may use one or more fiber optic splitters to divide individual optical fiber cables among two or more ONTs, thus reducing the number of fiber optic cables needed for connectivity and the number of active devices requiring electrical power. In some embodiments, downstream signals provided by an OLT are received by all ONTs. In some embodiments, the fiber optic terminals may include customer premise equipment (CPE), central office (CO), or head end (HE) facility terminals.

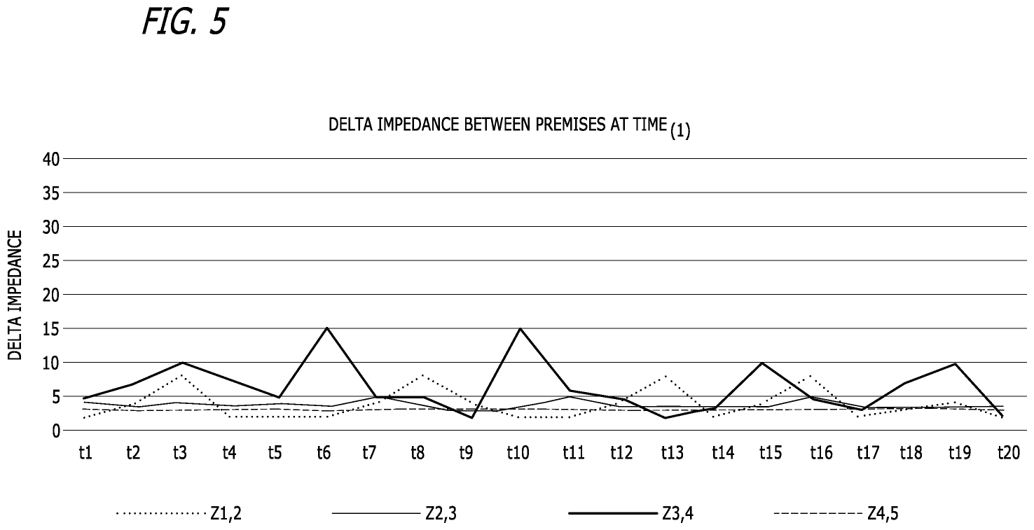

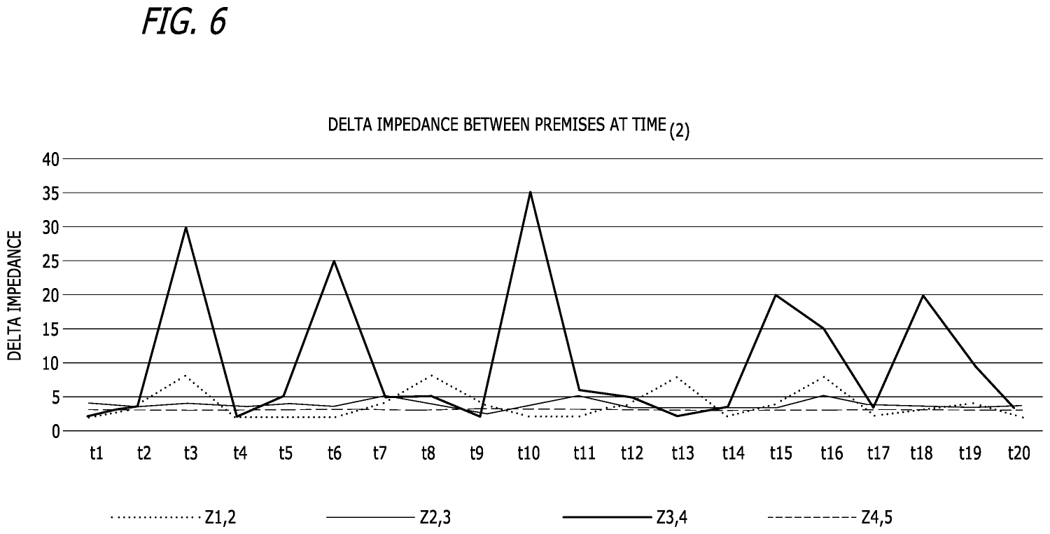

The control system 230 leverages the existence of the fiber optic network 240 to receive telemetry data (e.g., small data packets transmitted in sub-millisecond intervals) from various devices in the electrical power distribution environment 200. From this telemetry data, the control system may calculate various results that may be beneficially used for management of the electrical power distribution environment 200. For instance, impedance may be calculated at various points along an electric line, and a change in impedance (or delta impedance) may be calculated for electric line segments between two devices. By doing so, the effect of various environmental impacts on an electric line segment may be identified and categorized. In FIG. 2B, vegetation 250 is shown that may be affecting the delta impedance between customer premise 1 and customer premise 2. The specific impact of vegetation 250 on power loss between customer premises 1 and 2 may be estimated by measuring the change in impedance between meters located at customer premises 1 and 2 (e.g., the change in impedance Z₁ and Z₂). Similarly, vegetation 260 is shown between customer premise 3 and customer premise 4. The specific impact of vegetation 260 on power loss between customer premises 3 and 4 may be estimated by measuring the change in impedance between meters located at customer premises 3 and 4 (e.g., the change in impedance Z₃ and Z₄). In particular, the change in impedance between customer premises 3 and 4 may be determined to be larger than the change in impedance between customer premises 1 and 2, thereby indicating a larger vegetation presence and impact exists at a location between customer premises 3 and 4 than the vegetation presence and impact between customer premises 1 and 2. Evaluation of this impact is described further in connection with FIGS. 5 and 6 below.

Near real-time data capture from all active devices in the electric grid facilitates the capture of these impedance measurements, and may further facilitate capture of other types of information as well (e.g., voltage and current for each line segment). A non-contiguous electric wire defines a line segment. FIG. 2C illustrates an example diagram of a customer premise along with corresponding devices in nearby proximity to the customer premise from which measurements may be captured. Example electric line segments are from the transformer on one pole to the transformer on the next pole and from the transformer along the service line to the electric meter on a building. Data capture from these various devices may occur in sub-second intervals. All changes in data capture may cause data transmission occurrences, whereas updates may be sent by configuration if no changes occur. Simultaneously storing and subsequent calculations may occur for each received data transmission, and the calculation performed may trigger alerts when they indicate significant changes in delta impedance or other measured characteristics.

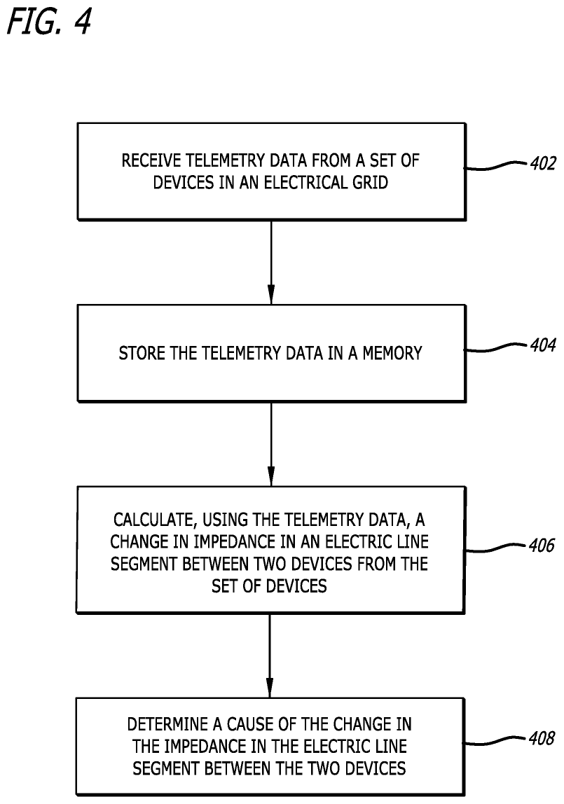

As described in in connection with FIG. 4 below, by identifying changes over time in delta impedance change, example embodiments may further utilize machine learning modeling to identify the likely extent of the delta impedance change, the rate at which is it change, and that the cause of the change in delta impedance is vegetation, thereby enabling proper prioritization of any necessary remediation.

Turning to FIG. 5, an example graph is shown that depicts the delta impedance between two premises at a first time. In turn, FIG. 6 illustrates an example graph showing delta impedance between two premises at a second time. The graph in FIG. 5 shows that at a particular time the trees between enterprise 3 and 4 have a higher impact over multiple readings than other segments. The graph in FIG. 6, with data taken at some time later (in this case, perhaps months later), shows that over time the impedance between enterprise 3 and 4 has increased significantly and action should be taken, whereas the vegetation between enterprises 1 and 2 can be deprioritized and addressed at a later time. This data collection and prioritization facilitates maximizing the efficiency of operations and maintenance spending. This same data can be modeled such that data captured immediately before an outage during a storm can give specific information about the location of a downed line faster without additional safety risks for workers.

Although a high level explanation of the operations of example embodiments has been provided above, specific details regarding the configuration of such example embodiments are provided below.

### Example Implementing Apparatuses

FIG. 3 illustrates an apparatus 300 that may comprise an example system device of control system 230 that may implement example embodiments described herein. The apparatus may include processor 302, memory 304, communications circuitry 306, and input-output circuitry 308, each of which will be described in greater detail below, along with and any number of additional hardware components not expressly shown in FIG. 3. While the various components are only illustrated in FIG. 3 as being connected with processor 302, it will be understood that the apparatus 300 may further comprises a bus (not expressly shown in FIG. 3) for passing information amongst any combination of the various components of the apparatus 300. The apparatus 300 may be configured to execute various operations described above, as well as those described below in connection with FIG. 3.

The processor 302 (and/or co-processor or any other processor assisting or otherwise associated with the processor) may be in communication with the memory 304 via a bus for passing information amongst components of the apparatus. The processor 302 may be embodied in a number of different ways and may, for example, include one or more processing devices configured to perform independently. Furthermore, the processor may include one or more processors configured in tandem via a bus to enable independent execution of software instructions, pipelining, and/or multithreading. The use of the term “processor” may be understood to include a single core processor, a multi-core processor, multiple processors of the apparatus 300, remote or “cloud” processors, or any combination thereof.

The processor 302 may be configured to execute software instructions stored in the memory 304 or otherwise accessible to the processor (e.g., software instructions stored on a separate storage device). In some cases, the processor may be configured to execute hard-coded functionality. As such, whether configured by hardware or software methods, or by a combination of hardware with software, the processor 302 represent an entity (e.g., physically embodied in circuitry) capable of performing operations according to various embodiments of the present invention while configured accordingly. Alternatively, as another example, when the processor 302 is embodied as an executor of software instructions, the software instructions may specifically configure the processor 302 to perform the algorithms and/or operations described herein when the software instructions are executed.

Memory 304 is non-transitory and may include, for example, one or more volatile and/or non-volatile memories. In other words, for example, the memory 304 may be an electronic storage device (e.g., a computer readable storage medium). The memory 304 may be configured to store information, data, content, applications, software instructions, or the like, for enabling the apparatus to carry out various functions in accordance with example embodiments contemplated herein.

The communications circuitry 306 may be any means such as a device or circuitry embodied in either hardware or a combination of hardware and software that is configured to receive and/or transmit data from/to a network and/or any other device, circuitry, or module in communication with the apparatus 300. In this regard, the communications circuitry 306 may include, for example, a network interface for enabling communications with a wired or wireless communication network. For example, the communications circuitry 306 may include one or more network interface cards, antennas, buses, switches, routers, modems, and supporting hardware and/or software, or any other device suitable for enabling communications via a network. Furthermore, the communications circuitry 306 may include the processing circuitry for causing transmission of such signals to a network or for handling receipt of signals received from a network.

The apparatus 300 may include input-output circuitry 308 configured to provide output to a user and, in some embodiments, to receive an indication of user input. It will be noted that some embodiments will not include input-output circuitry 308, in which case user input may be received via a separate device. The input-output circuitry 308 may comprise a user interface, such as a display, and may further comprise the components that govern use of the user interface, such as a web browser, mobile application, dedicated client device, or the like. In some embodiments, the input-output circuitry 308 may include a keyboard, a mouse, a touch screen, touch areas, soft keys, a microphone, a speaker, and/or other input/output mechanisms. The input-output circuitry 308 may utilize the processor 302 to control one or more functions of one or more of these user interface elements through software instructions (e.g., application software and/or system software, such as firmware) stored on a memory (e.g., memory 304) accessible to the processor 302.

In some embodiments, various components of the apparatus 300 may be hosted remotely (e.g., by one or more cloud servers) and thus not all components must reside in one physical location. Moreover, some of the functionality described herein may be provided by third party circuitry. For example, apparatus 300 may access one or more third party circuitries via any sort of networked connection that facilitates transmission of data and electronic information between the apparatus 300 and the third party circuitries. In turn, the apparatus 300 may be in remote communication with one or more of the components describe above as comprising the apparatus 300.

As will be appreciated based on this disclosure, some example embodiments may take the form of a computer program product comprising software instructions stored on at least one non-transitory computer-readable storage medium (e.g., memory 304). Any suitable non-transitory computer-readable storage medium may be utilized in such embodiments, some examples of which are non-transitory hard disks, CD-ROMs, flash memory, optical storage devices, and magnetic storage devices. It should be appreciated, with respect to certain devices embodied by apparatus 300 as described in FIG. 3, that loading the software instructions onto a computing device or apparatus produces a special-purpose machine comprising the means for implementing various functions described herein.

Having described specific components of the apparatus 300, example embodiments are described below.

### Example Operations

Turning to FIG. 4, an example flowchart is illustrated that contains example operations implemented by various embodiments contemplated herein. The operations illustrated in FIG. 4 may, for example, be performed by an apparatus 300, which is shown and described in connection with FIG. 3. To perform the operations described below, the apparatus 300 may utilize one or more of processor 302, memory 304, communications circuitry 306, input-output circuitry 308, other components, and/or any combination thereof. It will be understood that user interaction with the apparatus 300 may occur directly via input-output circuitry 308, or may instead be facilitated by a device that in turn interacts with apparatus 300.

As shown by operation 402, the apparatus 300 includes means, such as processor 302, memory 304, communications circuitry 306, input-output circuitry 308, or the like, for receiving telemetry data from a set of devices in an electrical grid. The telemetry data may be received via a fiber optic network, which may be a passive-optical network. The use of CWDM, DWDM, or any other multiplexing technique may permit near-real-time telemetry data to be collected from any number of devices over the fiber optic network infrastructure. The telemetry data may include impedance, voltage, or current at a position along an electric line corresponding to the particular device from which the telemetry data is received. It will be appreciated that in some implementations, an alternative method of transmitting the telemetry data may be utilized besides a fiber optic network (e.g., any other Internet-based communications). The set of devices may include any entities located within the electrical power distribution environment 200, such as smart meters at customer premises, transformers, down-line reclosers, and distributed power generation facilities. These devices may transmit the telemetry data periodically at any desired frequency (e.g., sub-second intervals, sub-millisecond intervals, or the like).

As shown by operation 404, the apparatus 300 includes means, such as processor 302, memory 304, communications circuitry 306, input-output circuitry 308, or the like, for storing the telemetry data in a memory. In some embodiments, the stored telemetry data may be accessed later for calculation purposes.

In some embodiments, the stored telemetry data may be used as training data for one or more stored machine learning models, which may be trained using the stored telemetry data as is or modified telemetry data (e.g., labelled by users). The particular machine learning models may be discussed in greater detail below in operation 408.

As shown by operation 406, the apparatus 300 includes means, such as processor 302, memory 304, communications circuitry 306, input-output circuitry 308, or the like, for calculating, using the telemetry data, a change in impedance in an electric line segment between two devices from the set of devices. To this end, calculating the change in the impedance in the electric line segment between the two devices may include retrieving impedance measurements from the two devices, and calculating a difference between the impedance measurements received from the two devices.

In some embodiments, the telemetry data received from each particular device may not include an impedance measurement by the particular device. In such embodiments, to retrieve an impedance measurement for a given device, the apparatus 300 may further include means, such as processor 302, memory 304, communications circuitry 306, input-output circuitry 308, or the like, for deriving the impedance. For instance, the apparatus 300 may utilize the following equation to calculate impedance at a particular device:

Z=\sqrt{R²+(X_{L}−X_{c})²},

where Z is the calculated impedance, and R is resistance, X_{L} is inductive reactance, and X_{C} is capacitive reactance, each of which may be gathered for the particular device.

Once the impedance is known from both of the two devices, the change in impedance may thereafter be calculated in a straightforward manner. For instance, where Z₁ is an impedance measurement from a first device and Z₂ is an impedance measurement from a second device, ΔZ_{1,2} (the change in impedance of the electric line between the first device and the second device) may be calculated through the arithmetic operation ΔZ_{1,2}=Z₂−Z₁.

Finally, as shown by operation 408, the apparatus 300 includes means, such as processor 302, memory 304, communications circuitry 306, input-output circuitry 308, or the like, for determining a cause of the change in the impedance in the electric line segment between the two devices. In some implementations, the apparatus 300 may determine the cause of the change in the impedance in the electric line segment between the two devices using a machine learning model trained to process the change in impedance to generate a cause of the change in impedance. The machine learning model may process the change in impedance and output a determined cause for the change.

In some embodiments, the determined cause may describe a determined cause category. A determined cause category may include a “mild vegetation”, “moderate vegetation”, “severe vegetation” category. The particular determined cause category may be indicative of the vegetation extent on the electric line segment. For example, a mild vegetation category may correspond to when vegetation is infrequently brushing on the electric line segment, a moderate vegetation category may correspond to when vegetation is persistently touching on the electric line segment, and a severe vegetation category may correspond to when vegetation is persistently leaning on the electric line segment.

In some embodiments, the determined cause output by the machine learning model may further indicate a predicted cause location between in the line segment between the two devices. For example, in a rural area, if the distance between two devices is large, the determined cause may further indicate a predicated cause location indicative of a likely location causing the change in impedance. The predicted cause location may be based on historical data for the particular line segment. For example, a particular tree located at a particular location between customer premises 3 and 4 may frequently be the cause of the change in impedance. As will be described below, historical change in impedance data may be labeled with the known cause of the change in impedance (e.g., tree at location XYZ) such that the machine learning model may further refine the cause of the change in impedance between two devices to a narrower location (e.g., the particular tree location). As such, an operation and maintenance crew may more quickly and efficiently identify and respond to problematic vegetation.

In some embodiments, the machine learning model may be a neural network, such as a convolutional neural network (CNN). In some embodiments, the machine learning model is a classification machine learning model and in particular, may provide multi-class classification, multi-label classification, or imbalanced classification. In some embodiments, the machine learning model is a trained machine learning model which may be trained and/or periodically retrained. The machine learning model may be trained and/or retrained by retrieving, from the memory, a plurality of previously calculated changes in the impedance in the electric line segment between the two devices. The machine learning model may process the plurality of previously calculated changes in the impedance in the electric line segment between the two devices to predict a physical or environmental impact causing the change in the impedance in the electric line segment. To this end, the machine learning model may be trained using historical data.

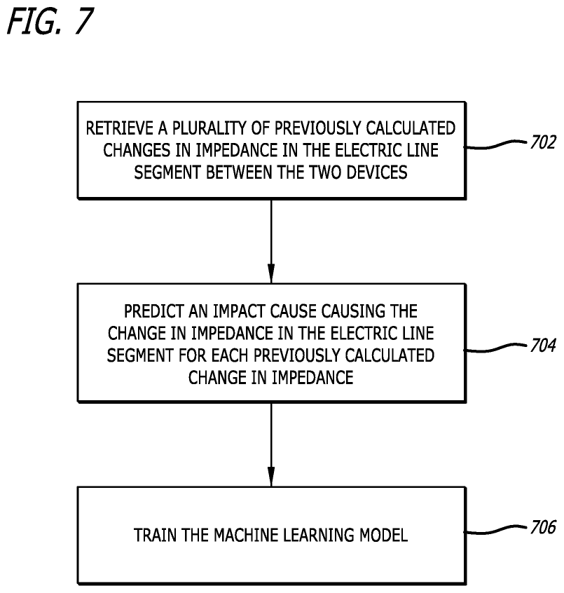

FIG. 7 illustrates and example training routine that may be used to train and/or retrain the machine learning model. As shown by operation 702, the apparatus 300 includes means, such as processor 302, memory 304, communications circuitry 306, input-output circuitry 308, or the like, for retrieving a plurality of previously calculated changes in impedance in the electric line segment between the two devices. This retrieved data may correspond to a historical training data set comprising data regarding historical changes in impedance in electric lines and known causes for evolution between the changes in the impedance in the electric lines.

As shown by operation 704, the apparatus 300 includes means, such as processor 302, memory 304, communications circuitry 306, input-output circuitry 308, or the like, for predicting a physical or environmental impact causing the change in impedance in the electric line segment. The machine learning model may be configured to process the retrieved plurality of data to generate a predicted impact cause. The predicted impact cause may be the predicted physical or environmental impact causing the change in impedance in the electric line segment as determined by the machine learning model.

As shown by operation 706, the apparatus 300 includes means, such as processor 302, memory 304, communications circuitry 306, input-output circuitry 308, or the like, for training the machine learning model. The historical training data set may include label indicative of the known impact cause for each change in impedance. The output predicted impact cause may be compared to the known impact cause for each change in impedance using any suitable machine learning techniques, such as gradient boosting, random forests, decision trees, logistic regression, support vector machines, etc. The machine learning model may be trained periodically and/or semi-periodically using the historical training data set to improve the accuracy of the machine learning model.

It should be understood that determining a cause of the change in impedance in the electric line segment may further be enhanced by allowing input from downstream demand to provide complete situational analysis. For instance, input from downstream demand may identify the need for adjustments that account for changes, such as those experienced due to single-phase motor starts and stops, (i.e. washing machines, dryers, power tools, or the like).

Moreover, in various embodiments, certain calculations performed by the apparatus 300 may be performed via distributed elements of the apparatus 300. For instance, a distributed processing design may in some cases allow for the segregation of rapid processing demands through different databases for near-real-time calculations and long-term data analysis, facilitating scalability and agility.

FIGS. 4 and 7 illustrate operations performed by apparatuses, methods, and computer program products according to various example embodiments. It will be understood that each flowchart block, and each combination of flowchart blocks, may be implemented by various means, embodied as hardware, firmware, circuitry, and/or other devices associated with execution of software including one or more software instructions. For example, one or more of the operations described above may be embodied by software instructions. In this regard, the software instructions which embody the procedures described above may be stored by a memory of an apparatus employing an embodiment of the present invention and executed by a processor of that apparatus. As will be appreciated, any such software instructions may be loaded onto a computing device or other programmable apparatus (e.g., hardware) to produce a machine, such that the resulting computing device or other programmable apparatus implements the functions specified in the flowchart blocks. These software instructions may also be stored in a computer-readable memory that may direct a computing device or other programmable apparatus to function in a particular manner, such that the software instructions stored in the computer-readable memory produce an article of manufacture, the execution of which implements the functions specified in the flowchart blocks. The software instructions may also be loaded onto a computing device or other programmable apparatus to cause a series of operations to be performed on the computing device or other programmable apparatus to produce a computer-implemented process such that the software instructions executed on the computing device or other programmable apparatus provide operations for implementing the functions specified in the flowchart blocks.

The flowchart blocks support combinations of means for performing the specified functions and combinations of operations for performing the specified functions. It will be understood that individual flowchart blocks, and/or combinations of flowchart blocks, can be implemented by special purpose hardware-based computing devices which perform the specified functions, or combinations of special purpose hardware and software instructions.

In some embodiments, some of the operations above may be modified or further amplified. Furthermore, in some embodiments, additional optional operations may be included. Modifications, amplifications, or additions to the operations above may be performed in any order and in any combination.

### CONCLUSION

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method for predicting causes of changes in power loss along electric line segments, the method comprising:
receiving, by a control system, telemetry data from a set of devices in an electrical grid;
storing, by the control system, the telemetry data in a memory;
calculating, by the control system and using the telemetry data, a change in impedance in an electric line segment between two devices from the set of devices; and
determining, by the control system, a cause of the change in the impedance in the electric line segment between the two devices.

2. The method of claim 1, wherein the telemetry data is received via a fiber optic network.

3. The method of claim 2, wherein the telemetry data is received via passive-optical networking.

4. The method of claim 1, wherein the telemetry data from a particular device in the set of devices includes impedance, voltage, or current at a position along an electric line corresponding to the particular device.

5. The method of claim 1, wherein the control system receives the telemetry data from the set of devices periodically.

6. The method of claim 5, wherein the control system receives the telemetry data from the set of devices at sub-second intervals.

7. The method of claim 1, wherein the set of devices comprise smart meters at customer premises, transformers, down-line reclosers, and distributed power generation facilities.

8. The method of claim 1, wherein calculating the change in the impedance in the electric line segment between the two devices includes:
retrieving, by the control system, measures of the impedance in the electric line segment from the two devices; and
calculating, by the control system, a difference between the measures of the impedance in the electric line segment from the two devices.

9. The method of claim 1, wherein determining the cause of the change in the impedance in the electric line segment between the two devices includes:
retrieving, by the control system and from the memory, a plurality of previously calculated changes in the impedance in the electric line segment between the two devices; and
predicting, using a machine learning model and the plurality of previously calculated changes in the impedance in the electric line segment between the two devices, a physical or environmental impact causing the change in the impedance in the electric line segment.

10. The method of claim 9, further comprising:
training, by the control system, the machine learning model using a historical training data set comprising data regarding historical changes in impedance in electric lines and known causes for evolution between the changes in the impedance in the electric lines.

11. An apparatus for predicting causes of changes in power loss along electric line segments, the apparatus comprising a processor and a memory storing software instructions that, when executed by the processor, cause the apparatus to:
receive telemetry data from a set of devices in an electrical grid;
store the telemetry data in a memory;
calculate, using the telemetry data, a change in impedance in an electric line segment between two devices from the set of devices; and
determine a cause of the change in the impedance in the electric line segment between the two devices.

12. The apparatus of claim 11, wherein the telemetry data is received via a fiber optic network.

13. The apparatus of claim 12, wherein the telemetry data is received via passive-optical networking.

14. The apparatus of claim 13, wherein the telemetry data from a particular device in the set of devices includes impedance, voltage, or current at a position along an electric line corresponding to the particular device.

15. The apparatus of claim 14, wherein the telemetry data is received from the set of devices periodically.

16. The apparatus of claim 15, wherein the telemetry data is received from the set of devices at sub-second intervals.

17. The apparatus of claim 16, wherein the set of devices comprise smart meters at customer premises, transformers, down-line reclosers, and distributed power generation facilities.

18. The apparatus of claim 17, wherein the processor and the memory storing software instructions, when executed by the processor and while calculating the change in impedance in the electric line segment between the two devices, cause the apparatus to:
retrieve measures of the impedance in the electric line segment from the two devices; and
calculate a difference between the measures of the impedance in the electric line segment from the two devices.

19. The apparatus of claim 11, wherein the processor and the memory storing software instructions, when executed by the processor and while determining the cause of the change in the impedance in the electric line segment between the two devices, cause the apparatus to:
retrieve, from the memory, a plurality of previously calculated changes in the impedance in the electric line segment between the two devices; and
predict, using a machine learning model and the plurality of previously calculated changes in the impedance in the electric line segment between the two devices, a physical or environmental impact causing the change in the impedance in the electric line segment.

20. A computer program product for predicting causes of changes in power loss along electric line segments, the computer program product comprising at least one non-transitory computer-readable storage medium storing software instructions that, when executed by an apparatus, cause the apparatus to:
receive telemetry data from a set of devices in an electrical grid;
store the telemetry data in a memory;
calculate, using the telemetry data, a change in impedance in an electric line segment between two devices from the set of devices; and
determine a cause of the change in the impedance in the electric line segment between the two devices.
